(19) United States
(12) Patent Application Publication
(10) Pub. No.: US 2023/0395376 A1
(43) Pub. Date: Dec. 7, 2023

(54) SEMICONDUCTOR SUBSTRATES AND METHODS OF PRODUCING THE SAME

(71) Applicant: IMEC vzw, Leuven (BE)

(72) Inventors: Bertrand Parvais, Nil-Saint-Vincent (BE); Sachin Yadav, Leuven (BE); Ming Zhao, Bertem (BE); Pieter Cardinael, Auderghem (BE)

(21) Appl. No.: 18/324,752

(22) Filed: May 26, 2023

(30) Foreign Application Priority Data
Jun. 2, 2022 (EP) 22176943.3

(51) Int. Cl. H01L 21/02; H01L 21/322; H01L 29/20

(52) U.S. Cl. CPC H01L 21/0254; H01L 21/02181; H01L 21/3223; H01L 29/2003; H01L 21/02381; H01L 21/02164; H01L 21/0245; H01L 21/02532

(57) ABSTRACT

In one aspect, a substrate includes a base substrate, a dielectric layer directly on the base substrate, a trap-rich layer directly on the dielectric layer, and a crystalline semiconductor layer directly on the trap-rich layer. The dielectric layer may be a stack of multiple dielectric sublayers formed of the same dielectric material or formed of two or more different dielectric materials. The substrate can be suitable to epitaxially grow on the surface of the crystalline semiconductor layer one or more layers of a compound semiconductor. One application is the growth of a stack of layers of III-V material with one or more upper layers of the stack being suitable to process in and/or on the layers a number of semiconductor devices such as transistors or diodes. The position of the trap-rich layer, between the dielectric layer and the crystalline semiconductor layer, can enable the neutralization of a parasitic surface conductive (PSC) layer at the interface between the crystalline layer and the compound layer or layers, and of an additional PSC layer caused by a direct contact between the crystalline layer and the dielectric layer. The disclosed technology is equally related to methods of producing the substrate of the disclosed technology.

### CROSS-REFERENCE TO RELATED APPLICATIONS

This application claims foreign priority to European Patent Application EP 22176943.3, filed Jun. 2, 2022, the content of which is incorporated by reference herein in its entirety.

### BACKGROUND

### Technical Field

The disclosed technology is related to semiconductor processing, and more particularly to a substrate suitable to produce thereon an epitaxially grown stack of compound semiconductor layers such as layers formed of aluminum nitride (AlN), gallium nitride (GaN), aluminum gallium nitride (AlGaN), gallium arsenide (GaAs), indium phosphide (InP), gallium antimonide (GaSb) or other III-V materials.

### Description of the Related Technology

The epitaxial growth of compound semiconductors, in particular III-V materials on silicon has been a widely researched field in view of present and future generations of substrates suitable for the fabrication of high-performance semiconductor devices. Notably radio-frequency (RF) applications will likely increasingly use III-V materials because of their superior low-noise and high power characteristics as compared to their silicon CMOS counterparts. Consequently, implementation of low-noise amplifiers, power amplifiers, and switches for RF front-end-of-module (FEM) can be based on III-V materials for 5G and beyond wireless applications.

Integration of III-V materials such as GaN, GaAs, and InP on a large-area silicon substrate can be a key to achieve low cost, high volume production. In order to reduce and/or minimize RF losses in the substrate and to achieve good switch linearity, the III-V materials can be grown on a high resistivity crystalline silicon layer, which may for example, be the active silicon (Si) layer of a silicon-on-insulator (SOI) substrate. Nevertheless, the resistivity of the Si layer generally decreases as a consequence of III-V material diffusing in the Si during the high-temperature epitaxial growth of the material. The diffused III-V material can have the effect of doping the Si, thereby causing the formation of a parasitic surface conductive (PSC) layer located in the high resistivity Si layer, at the interface between the Si and the III-V layer stack. This PSC layer can be a root cause of the majority of RF losses and harmonic generation in the high resistivity substrate.

A typical solution applied to mitigate the PSC layers can be the formation of a trap rich (TR) layer. It is known to form a TR layer underneath the oxide layer of an SOI wafer, to thereby neutralize free charges in the base substrate of the SOI wafer, when RF circuitry is formed directly on the Si top layer of the SOI. Examples of this approach are disclosed in patent publication documents EP3367424 and US2020/006385. This is however not a solution for mitigating the losses caused by the formation of III-V layers on the Si top layer.

Patent publication document US2016/0351666 describes a method for forming a trap rich layer at the interface between the high resistivity Si and the III-V stack, by irradiating the substrate with a laser after the epitaxial growth of the III-V material. This is a complex method and the impact of the laser on the substrate characteristics may be unpredictable. However, doping of the Si by diffusion of III-V material may not be the only source of reduced resistivity in a high resistivity Si layer formed on top of a dielectric layer such as a layer of silicon oxide. Positive charges appear in the oxide layer, which can be compensated by negative charges in the Si layer, resulting in a PSC at the oxide/Si interface. It is at least doubtful whether the negative effect of this PSC is mitigated by the approach described in US2016/0351666.

### SUMMARY OF CERTAIN INVENTIVE ASPECTS

The disclosed technology aims to provide a solution to the above-described problems. This aim can be achieved by various implementations of a substrate and by production methods in accordance with the appended claims.

A substrate according to the disclosed technology can include a base substrate, a dielectric layer (e.g., directly) on the base substrate, a trap-rich layer (e.g., directly) on the dielectric layer, and a crystalline semiconductor layer (e.g., directly) on the trap-rich layer. The dielectric layer may be a stack of multiple dielectric sublayers formed of the same dielectric material or formed of two or more different dielectric materials. The substrate of the disclosed technology can be suitable to epitaxially grow on the surface of the crystalline semiconductor layer one or more layers of a compound semiconductor. An example application is the growth of a stack of layers of III-V material with one or more upper layers of the stack being suitable to process in and/or on the layers, a number of semiconductor devices such as transistors or diodes. Such III-V materials include GaN, GaAs, InP, GaSb or others. The position of the trap-rich layer, between the dielectric layer and the crystalline semiconductor layer, can enable the neutralization of a parasitic surface conductive layer at the interface between the crystalline layer and the compound layer or layers, and of an additional PSC layer caused by (e.g., a direct) contact between the crystalline layer and the dielectric layer.

Hence the substrate of the disclosed technology can be a low loss substrate, e.g., a substrate that reduces and/or prevents RF energy loss when active devices are produced on the compound semiconductor layers. This can be particularly useful in the case of RF devices and circuits fabricated on III-V layers formed on a substrate according to the disclosed technology. The disclosed technology can be equally related to methods of producing the substrate of the disclosed technology.

The fact that the crystalline semiconductor layer lies (e.g., directly) on the trap-rich layer, e.g., that these layers are in (e.g., direct) mutual contact along a physical interface, distinguishes the disclosed technology from other SOI substrates where the insulator layer of the SOI structure lies between the trap-rich layer and the crystalline semiconductor layer.

The disclosed technology can be thus related to a substrate suitable to grow thereon one or more compound semiconductor layers, the substrate including the following consecutive parts, from the bottom of the substrate to the top: a base substrate, (e.g., directly) on the base substrate, a dielectric layer, which may be a single layer or a stack of multiple dielectric layers, a trap-rich layer (e.g., directly) on the dielectric layer, and a crystalline semiconductor layer (e.g., directly) on the trap-rich layer.

According to an embodiment, the base substrate is a silicon substrate or a ceramic substrate. The substrate may include a stack of dielectric layers on the base substrate, the stack including a top layer of silicon oxide.

According to an embodiment, the trap-rich layer is a layer of polysilicon. According to an embodiment, the substrate is suitable to grow thereon one or more layers of III-V semiconductor material. The crystalline semiconductor layer may be a crystalline silicon layer.

The disclosed technology can also be related to a substrate according to any of the above embodiments, and further including one or more compound semiconductor layers (e.g., directly) on the crystalline semiconductor layer. This may for example, be one or more III-V layers, such as a stack including an AlGaN/AlN superlattice buffer layer, a GaN channel layer, and/or an AlGaN barrier layer.

The disclosed technology can also be related to a method of producing a substrate according to any one of the preceding embodiments, the method including: providing a base substrate, forming a first dielectric layer (e.g., directly) on the base substrate, providing a crystalline semiconductor substrate, forming a trap-rich layer (e.g., directly) on the crystalline semiconductor substrate, optionally forming a second dielectric layer (e.g., directly) on the trap rich layer, bonding the crystalline semiconductor substrate to the base substrate by bonding the second dielectric layer to the first dielectric layer, or by bonding the trap-rich layer (e.g., directly) to the first dielectric layer, removing part of the crystalline semiconductor substrate, and leaving a layer of crystalline semiconductor material on the trap-rich layer.

According to an embodiment, the method can include doping the crystalline substrate to create a line of cracks in the substrate, where the removing part of the crystalline substrate includes removing the part along the line of cracks.

According to an embodiment of the method of the disclosed technology, the base substrate is a silicon substrate or a ceramic substrate.

According to an embodiment of the method of the disclosed technology, the trap-rich layer is a layer of polysilicon.

According to an embodiment of the method of the disclosed technology, the crystalline semiconductor substrate is a crystalline silicon substrate.

The disclosed technology can be equally related to a semiconductor chip including a singulated portion of a substrate according to the disclosed technology, the chip including one or more semiconductor devices produced from one or more compound semiconductor layers grown (e.g., present) on the substrate.

### BRIEF DESCRIPTION OF THE DRAWINGS

FIG. 1A illustrates an example substrate in accordance with an embodiment of the disclosed technology.

FIG. 1B shows the substrate of FIG. 1A, with a stack of III-V materials produced thereon.

FIGS. 2A, 2B, 2C, and 2D illustrate various intermediate structures of one embodiment of the method of the disclosed technology, of producing the substrate illustrated in FIG. 1A.

### DETAILED DESCRIPTION OF CERTAIN ILLUSTRATIVE EMBODIMENTS

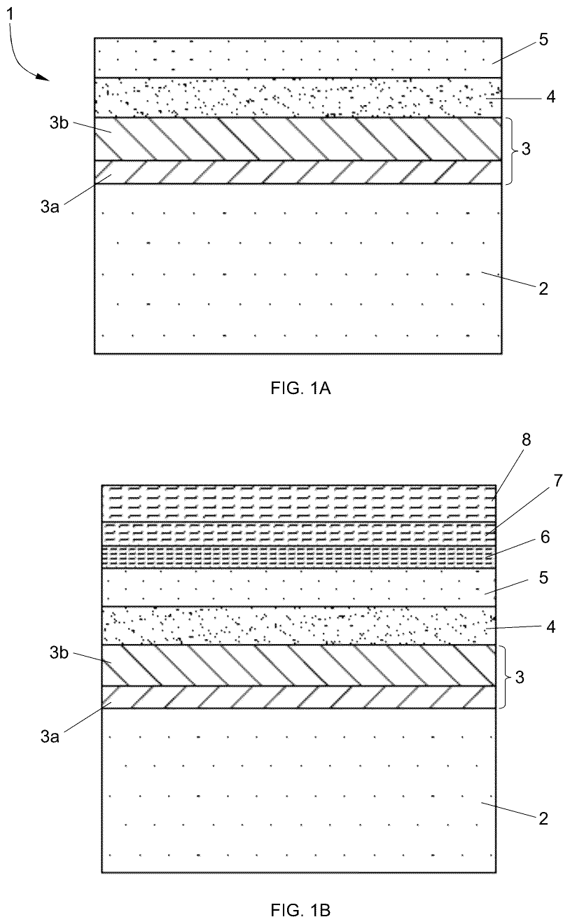

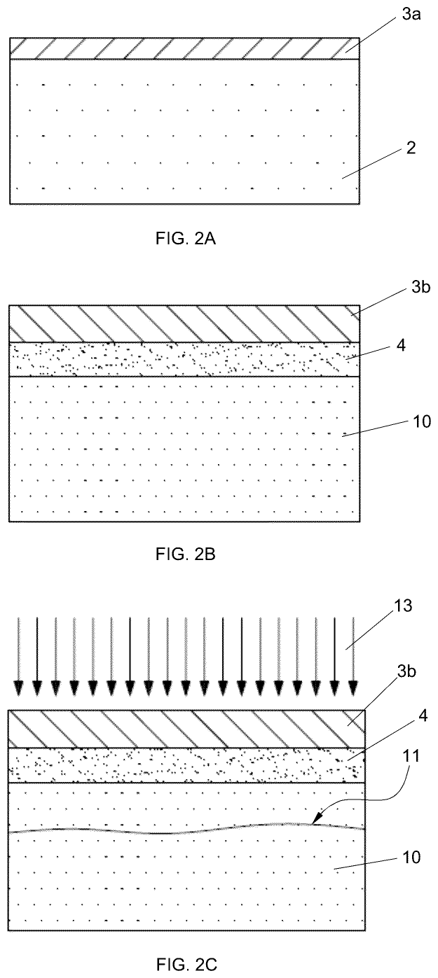

FIG. 1A shows a small section of a substrate 1 according to an embodiment of the disclosed technology. The substrate may have the planar dimensions of a process wafer, for example, a 300 mm diameter wafer. Materials and layer thicknesses mentioned hereafter are cited only by way of example and are not limiting the scope of the disclosed technology.

The substrate 1 can include a crystalline silicon base substrate 2 with a number of layers thereon. On (e.g., directly) the base substrate 2 is a dielectric layer 3, having a stack of two sublayers 3a and 3b. Layer 3a may for example, be a silicon nitride layer or it may itself be a stack of a silicon oxide layer and a silicon nitride layer. In the embodiment shown, layer 3b is a silicon oxide layer. The thickness of each of the layers 3a and 3b may be between a few tens of nanometers up to a few micrometers.

On (e.g., directly) the dielectric layer 3 is a polycrystalline silicon (polySi) layer 4, which may have a thickness in the order of 1 μm and (e.g., directly) on the polySi layer 4 is a crystalline silicon layer 5 having a thickness in the order of 0.5 μm, but below the actual value of 0.5 μm in some cases. Layer 5 can be a high resistance (HR) Si layer, having a resistivity of for example, more than 100 Ω·cm.

Methods to produce the substrate 1 will be described further in this description.

FIG. 1B shows the substrate 1 provided with a stack of III-V materials obtained by epitaxial growth. In the embodiment shown, and included merely by way of example, the III-V stack includes a thin nucleation layer e.g., AlN (not shown) (e.g., directly) on the Si layer 5, followed by a buffer layer 6 and active layers 7 and 8 on the buffer layer. The buffer layer can serve to compensate for the difference in lattice constant between the Si layer 5 and the active layers 7, 8 of the III-V stack. The buffer layer 6 may be a stack of III-V material such as AlGaN alloy, GaN, and/or AlGaN/AlN superlattice. The active layers may include a channel layer 7 and a barrier layer 8 designed to create a 2-dimensional charge carrier layer at the interface between the channel and the barrier. The channel layer 7 may be formed of defect-free GaN and the barrier layer 8 may be formed of AlGaN, which are typically used for producing a GaN based HEMT (High Electron Mobility Transistor).

The polySi layer 4 can act as a trap-rich layer, e.g., a layer capable of trapping free charges appearing in a given area above or below the trap-rich layer 4. The so-called traps in a polySi layer or in a trap-rich layer formed of other material may be crystal defects or deliberately added dopant elements. In a substrate according to the disclosed technology, the trap rich layer 4 can be configured, due to its material and thickness, to trap free charges appearing in a PSC layer at the interface between III-V stack 6-7-8 and the crystalline layer 5, thereby neutralizing the PSC layer. At the same time, due to its position between the crystalline layer 5 and the dielectric layer 3, the trap-rich layer 4 can enable the neutralization of an additional PSC layer appearing where the crystalline layer 5 is in (e.g., direct) contact with the dielectric layer 3.

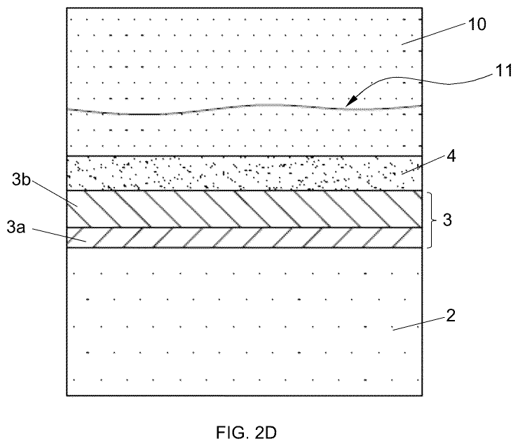

With reference to FIGS. 2A to 2D, one embodiment of the method of producing the substrate 1 is described hereafter. Once again, materials are cited only by way of example and are not limiting the scope of the disclosed technology.

As shown in FIG. 2A, the silicon base substrate 2 can be provided and the dielectric layer 3a can be produced (e.g., directly) thereon by any suitable technique known in the art, such as chemical vapour deposition (CVD), possibly applying several consecutive layers of different dielectric materials.

With reference to FIG. 2B, a high resistance crystalline silicon substrate 10 can be provided and the trap-rich layer 4 of polycrystalline silicon, also referred to herein as polySi, can be formed (e.g., directly) thereon, for example by CVD, followed by the deposition of the silicon oxide layer 3b, for example again by CVD.

As illustrated in FIG. 2C, the substrate 10 can be provided with layers 4 and 3b can be subjected to a dopant implantation 13, e.g., using hydrogen atoms as dopants. The implant energy and duration can be chosen so that the implant causes a zone of small cracks to appear in the crystalline silicon substrate 10, symbolized by the line 11 in FIG. 2C.

With reference to FIG. 2D, the substrate 10 provided with layers 4 and 3b can be flipped and bonded to base substrate 2 by bonding the layer 3b to the layer 3a, by (e.g., a direct) dielectric-to-dielectric bonding. The bulk Si substrate 10 (above the line 11) can be separated using heating and the remaining silicon layer can be planarized by chemical mechanical polishing (CMP), leaving a thin crystalline Si layer 5 on top of the polysilicon layer 4, as shown in FIG. 1A.

The use of an H-implant (e.g., by ion-implanting hydrogen ions) to form small cracks in the silicon and the subsequent removal of the silicon substrate along the line of cracks is known as a ‘smart cut’. Details of how to perform this technique are considered known and are not described here in detail. An advantage of using this technique is that the Si-substrate 10 can be re-used to produce additional substrates according to the disclosed technology or for other purposes.

The method of the disclosed technology is however not limited by the use of the smart cut technique. As an alternative, the Si substrate 10 may be thinned after bonding, by grinding followed by chemical mechanical polishing of the silicon from the back side of the substrate 10, until the thin Si layer 5 remains.

As stated, the materials cited above are not limiting the scope of the disclosed technology. The base substrate 2 could be a ceramic substrate instead of a silicon substrate. According to various embodiments, the base substrate 2 itself also can include charge traps. This may be realized by a trap-rich crystalline silicon substrate, e.g., a silicon substrate having a trap-rich upper layer, such as obtainable by techniques known in the art of producing a trap-rich SOI wafer. Alternatively, the base substrate 2 could be formed of quartz or of polycrystalline AlN.

The trap-rich layer 4 could be formed of other materials instead of polySi. It could for example be an oxide layer obtainable by atomic layer deposition (ALD), such as a layer of hafnium oxide (HfO₂), which can exhibit a high interface trap density with Si.

The thickness of the trap-rich layer 4 may vary between a few tens of nanometers up to a few micrometers.

The dielectric layer 3 could be a single layer of a given material, for example, obtained by the method described above, but where both layers 3a and 3b are formed of silicon oxide. Layers 3a and 3b may then merge during bonding to form a substantially uniform silicon oxide layer 3.

According to another embodiment of the method of the disclosed technology, no dielectric layer 3b is deposited on the trap rich layer 4 prior to bonding, e.g., the trap rich layer 4 is bonded (e.g., directly) to the dielectric layer 3a. This is possible for specific material combinations, for example, when the trap rich layer 4 is a layer of hafnium oxide (HfO₂) and the dielectric layer 3a is a silicon oxide layer or includes an upper layer formed of silicon oxide.

A substrate in accordance with the disclosed technology can be further processed to produce a plurality of semiconductor devices from one or more compound semiconductor layers grown on the substrate. Further processing can be done by processing known as such in the art, for example processing to produce RF devices from III-V layers 6-8 deposited on the substrate 1 illustrated in the drawings. The disclosed technology is equally related to a semiconductor chip produced by singulating a substrate in accordance with the disclosed technology, after further processing of the substrate.

While the disclosed technology has been illustrated and described in detail in the drawings and foregoing description, such illustration and description are to be considered illustrative or exemplary and not restrictive. Other variations to the disclosed embodiments can be understood and effected by those skilled in the art in practicing the claimed disclosed technology, from a study of the drawings, the disclosure and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage.

What is claimed is:

1. A substrate suitable to grow thereon one or more compound semiconductor layers, the substrate comprising the following consecutive parts, from the bottom of the substrate to the top:
a base substrate;
a dielectric layer directly on the base substrate, wherein the dielectric layer is a single layer or a stack of multiple dielectric layers;
a trap-rich layer directly on the dielectric layer; and
a crystalline semiconductor layer directly on the trap-rich layer.

2. The substrate according to claim 1, wherein the base substrate is a silicon substrate or a ceramic substrate.

3. The substrate according to claim 1, comprising a stack of dielectric layers on the base substrate, said stack comprising a top layer of silicon oxide.

4. The substrate according to claim 1, wherein the trap-rich layer is configured to trap free charges above or below the trap-rich layer.

5. The substrate according to claim 1, wherein the trap-rich layer comprises traps of crystal defects or dopants.

6. The substrate according to claim 1, wherein the trap-rich layer is a layer of polysilicon.

7. The substrate according to claim 1, wherein the trap-rich layer is a layer of hafnium oxide.

8. The substrate according to claim 1, wherein the substrate is suitable to grow thereon one or more layers of one or more III-V semiconductor material(s).

9. The substrate according to claim 1, wherein the crystalline semiconductor layer is a crystalline silicon layer.

10. A substrate according to claim 1, further comprising one or more compound semiconductor layers directly on the crystalline semiconductor layer.

11. The substrate according to claim 10, wherein the one or more compound semiconductor layers are layers of one or more III-V semiconductor material(s).

12. A method of producing a substrate, the method comprising:
providing a base substrate;
forming a first dielectric layer directly on the base substrate;
providing a crystalline semiconductor substrate;
forming a trap-rich layer directly on the crystalline semiconductor substrate;
bonding the crystalline semiconductor substrate to the base substrate by bonding a second dielectric layer to the first dielectric layer, or by bonding the trap-rich layer directly to the first dielectric layer; and
removing part of the crystalline semiconductor substrate, leaving a layer of crystalline semiconductor material on the trap-rich layer.

13. The method according to claim 12, comprising doping the crystalline substrate to create a line of cracks in the substrate, and wherein removing part of the crystalline substrate includes removing the part along the line of cracks.

14. The method according to claim 12, wherein the base substrate is a silicon substrate or a ceramic substrate.

15. The method according to claim 12, wherein the trap-rich layer is configured to trap free charges above or below the trap-rich layer.

16. The method according to claim 12, wherein the trap-rich layer comprises traps of crystal defects or dopants.

17. The method according to claim 12, wherein the trap-rich layer is a layer of polysilicon.

18. The method according to claim 12, wherein the crystalline semiconductor substrate is a crystalline silicon substrate.

19. The method according to claim 12, further comprising forming the second dielectric layer directly on the trap-rich layer, wherein the bonding comprises bonding the second dielectric layer to the first dielectric layer.

20. A semiconductor chip comprising a singulated portion of a substrate according to claim 1, the chip comprising one or more semiconductor devices produced from one or more compound semiconductor layers grown on the substrate.
